(19) United States
(12) Patent Application Publication
(10) Pub. No.: US 2025/0372508 A1
(43) Pub. Date: Dec. 4, 2025

(54) INTEGRATED CIRCUIT STRUCTURE AND METHOD FOR FABRICATING THE SAME

(71) Applicants: TAIWAN SEMICONDUCTOR MANUFACTURING COMPANY, LTD., Hsinchu (TW); National Yang Ming Chiao Tung University, Hsinchu City (TW)

(72) Inventors: Chin-Yu LIU, Taipei City (TW); Hsin-Cheng LIN, Taipei City (TW); He-Wen SHEN, Taipei City (TW); Chee-Wee LIU, Taipei City (TW); Chenming HU, Oakland, CA (US)

(73) Assignees: TAIWAN SEMICONDUCTOR MANUFACTURING COMPANY, LTD., Hsinchu (TW); National Yang Ming Chiao Tung University, Hsinchu City (TW)

(21) Appl. No.: 18/733,148

(22) Filed: Jun. 4, 2024

(51) Int. Cl. H01L 23/522; H01L 21/768; H01L 23/367; H01L 23/528; H01L 23/538; H01L 29/06; H01L 29/40; H01L 29/417; H01L 29/423; H01L 29/66; H01L 29/775; H01L 29/786

(52) U.S. Cl. CPC H01L 23/5226; H01L 21/76802; H01L 21/7684; H01L 21/76843; H01L 21/76877; H01L 23/3672; H01L 23/5286; H01L 23/5383; H10D 30/014; H10D 30/031; H10D 30/43; H10D 30/6729; H10D 30/6735; H10D 30/6757; H10D 62/121; H10D 64/01

(57) ABSTRACT

A method for fabricating an integrated circuit structure is provided. The method include forming a semiconductor device over a semiconductor substrate, wherein the semiconductor device comprises a gate structure and first and second source/drain regions respectively on opposite sides of the gate structure; forming a frontside interconnect structure over a frontside of the semiconductor device, wherein the frontside interconnect structure comprise a frontside metal line and a frontside dielectric layer, and the frontside metal line is electrically connected to the first source/drain region of the semiconductor device; depositing a high-k dielectric layer over a backside of the semiconductor device, wherein a dielectric constant of the high-k dielectric layer is greater than about 3.9; etching an opening in the high-k dielectric layer to expose a backside of the second source/drain region; and forming a backside metal feature in the opening in the high-k dielectric layer.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-17 are cross-sectional views of an integrated circuit structure at various intermediate stages of manufacture according to some embodiments of the present disclosure.

FIG. 18 is a schematic view of an integrated circuit structure according to some embodiments of the present disclosure.

FIG. 19 illustrates a backside multilayer interconnection (MLI) structure according to some embodiments of the present disclosure.

FIG. 20 is a diagram illustrating voltage versus time of the integrated circuit structure according to some embodiments of the present disclosure.

FIGS. 21-23 illustrate a method for fabricating an integrated circuit structure at various intermediate stages of manufacture according to some embodiments of the present disclosure.

FIG. 24 illustrates a backside MLI structure according to some embodiments of the present disclosure.

FIG. 25 is a diagram illustrating noise reduction of integrated circuit structures with backside high-k dielectrics according to some embodiments of the present disclosure.

FIG. 26 is a cross-section view of a package structure according to some embodiments of the present disclosure.

FIG. 27 is a cross-section view of a package structure according to some embodiments of the present disclosure.

FIG. 28A is a schematic view of an integrated circuit structure according to some embodiments of the present disclosure.

FIG. 28B is a schematic view of an integrated circuit structure according to some embodiments of the present disclosure.

FIG. 29A is a schematic view of an integrated circuit structure according to some embodiments of the present disclosure.

FIG. 29B is a schematic view of an integrated circuit structure according to some embodiments of the present disclosure.

FIG. 30A is a schematic view of an integrated circuit structure according to some embodiments of the present disclosure.

FIG. 30B is a schematic view of an integrated circuit structure according to some embodiments of the present disclosure.

FIG. 31A is a schematic view of an integrated circuit structure according to some embodiments of the present disclosure.

FIG. 31B is a schematic view of an integrated circuit structure according to some embodiments of the present disclosure.

FIG. 32A is a schematic view of an integrated circuit structure according to some embodiments of the present disclosure.

FIG. 32B is a schematic view of an integrated circuit structure according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.”

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The term “multi-gate device” is used to describe a device (e.g., a semiconductor transistor) that has at least some gate material disposed on multiple sides of at least one channel of the device. In some examples, the multi-gate device may be referred to as a gate all around (GAA) device or a nanosheet device having gate material disposed on at least four sides of at least one channel of the device. The channel region may be referred to as a “nanowire,” which as used herein includes channel regions of various geometries (e.g., cylindrical, bar-shaped) and various dimensions. In some examples, the multi-gate device may be referred to as a FinFET device. However, one of ordinary skill would recognize that the teaching can apply to a single channel (e.g., single nanosheet) or any number of channels. One of ordinary skill may recognize other examples of semiconductor devices that may benefit from aspects of the present disclosure.

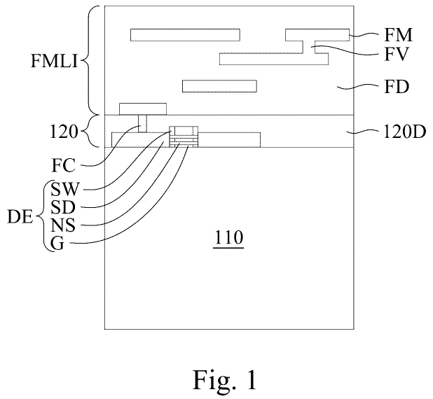

FIGS. 1-17 are cross-sectional views of an integrated circuit structure at various intermediate stages of manufacture according to some embodiments of the present disclosure. It is understood that additional operations may be provided before, during, and after the steps shown by FIGS. 1-17, and some of the steps described below can be replaced or eliminated for additional embodiments of the method. The order of the operations/processes may be interchangeable.

Reference is made to FIG. 1. In some embodiments, a substrate 110 is provided. The substrate 110 may comprise a substantially monocrystalline material, for example, bulk silicon. In some other embodiments, the substrate 110 may include another elementary semiconductor, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. In some embodiments, the substrate 110 may comprise an active layer of a semiconductor-on-insulator (SOI) substrate. An SOI substrate comprises a layer of a semiconductor material, such as silicon, formed on an insulator layer. The insulator layer may be, for example, a buried oxide (BOX) layer or a silicon oxide layer. The insulator layer is provided on a substrate, such as a silicon or glass substrate. Other substrates, such as multi-layered or gradient substrates, may also be used.

In some embodiments, one or more active and/or passive devices DE are formed on chip regions of the substrate 110. In the depicted embodiments, the devices DE are gate-all-around (GAA) transistors that are fabricated by channel stacking techniques, and stacked nanosheets NS can enhance the on-current (Iₒₙ) at fixed footprint. The cross-section shown in FIG. 1 is taken along a longitudinal axis of the nanosheets NS in a direction parallel to the direction of the current flow between the source/drain regions SD. The nanosheets NS may be formed by patterning an epitaxial stack including sacrificial layers and channel layers alternatively arranged over the substrate 110 using photolithography and etching techniques, follow by replacing the sacrificial layers with a gate structure G. In some embodiments, the gate structure G of the device DE illustrated in FIG. 1 may be a high-k, metal gate (HKMG) gate structure that may be formed using a gate-last process flow. FIG. 1 illustrates two nanosheets NS, although the devices DE may comprise any number of nanosheets. In some other embodiments, the devices DE include nanowires. In some other embodiments, the devices DE can be planar transistors or fin field-effect transistors (FinFET). The fin field-effect transistors (FinFET) are three-dimensional metal oxide semiconductor field effect transistor (MOSFET) structure formed in fin-like strips of semiconductor protrusions referred to as fins.

Source/drain regions SD are semiconductor regions in contact with the nanosheets NS. In some embodiments, the source/drain regions SD may comprise heavily-doped regions and relatively lightly-doped drain extensions. In some embodiments, the source/drain regions SD may comprise an epitaxially grown region. In FIG. 1, the devices DE may include spacers SW on opposite sidewall of the gate structure G. The spacers SW may space the gate structure G from the source/drain regions SD.

An interlayer dielectric (ILD) layer 120D may be deposited over the source/drain regions SD. A contact plug FC may be formed in the ILD layer 120D using photolithography, etching and deposition techniques. For example, a patterned mask may be formed over the ILD layer 120D and used to etch openings that extend through the ILD layer 120D to expose the gate structure G as well as the source/drain regions SD. Thereafter, conductive liner may be formed in the openings in the ILD layer 120D. Subsequently, the openings are filled with a conductive fill material (e.g., W, Al, Cu, Ru, Ni, Co, alloys of these, combinations thereof, and the like), using any acceptable deposition technique (e.g., CVD, ALD, PEALD, PECVD, PVD, ECP, electroless plating, or the like, or any combination thereof). Next, a planarization process (e.g., chemical mechanical process (CMP)) may be used to remove excess portions of all the conductive materials from over the surface of the ILD layer 120D. The resulting conductive plug FC extend into the ILD layer 120D and constitute contact plug FC making physical and electrical connections to the gate structures G or source/drain regions SD of the device DE. In the context, a combination of the device DE, the ILD layer 120D, and the contact plug FC may be referred to as a device layer 120. The device layer 120 may also be referred to a front-end-of-line structure in the context. In some embodiments, one or more devices DE are stacked one over another in the device layer 120. For example, a n-type device and a p-type device can be stacked one over another as a complementary field-effect transistor (CFET).

A front-side multilayer interconnection (MLI) structure FMLI is formed over a frontside of the device layer 120. The front-side MLI structure FMLI may include at least three front-side metallization layers. The number of front-side metallization layers may vary according to design specifications of the integrated circuit structure. The front-side metallization layers each comprise one or more front-side inter-metal dielectric (IMD) layers FD, one or more horizontal interconnects respectively extending horizontally in the IMD layers (e.g., metal lines FM), and one or more vertical interconnects respectively extending vertically in the IMD layers (e.g., metal via FV). The metal via FV connects the lower ones of the metal lines FM to the upper ones of the metal lines FM. The bottommost metallization layers (e.g., the metal lines FM) is in contact with the frontside contact plug FC to make signal electrical connection from the metal lines FM to the source/drain region SD.

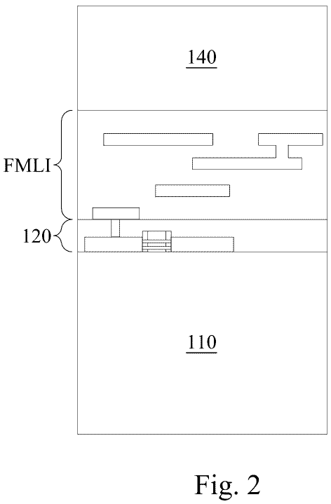

Reference is made to FIG. 2. The structure shown in FIG. 1 is bonded with a carrier substrate 140. A carrier substrate 140 is bonded the with substrate 110 through and the front-side MLI structure FMLI, so that processing of the backside of the substrate 110 can be performed. The carrier substrate 140 in the present embodiment may be similar to the substrate 110 and includes a silicon material. Alternatively, the carrier substrate 140 may include a glass substrate or another suitable material. The carrier substrate 140 may be bonded to the front-side MLI structure FMLI by molecular forces, such as direct bonding or optical fusion bonding, or by other bonding techniques, such as metal diffusion or anodic bonding.

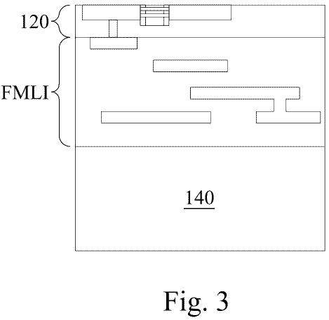

Reference is made to FIG. 3. One or more processes are performed to remove materials at the backsides of the source/drain regions SD, thereby exposing the backsides of the source/drain regions SD. For example, a planarization process (e.g., a CMP process, or a grinding process) is performed on the backside of the substrate 110, thereby thinning down the substrate 110. In some embodiments, after the planarization process, one or more etching process may be performed to remove the substrate 110.

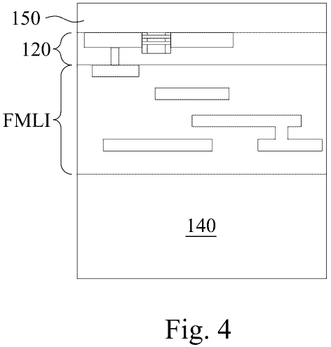

Reference is made to FIGS. 4-17 illustrates formation of the backside multilayer interconnection (MLI) structure BMLI over a backside of the device layer 120. Reference is made to FIG. 4. A backside dielectric layer 150 is deposited over the backsides of the source/drain regions SD, for example, by ALD, CVD, PVD, the like, or the combination thereof. The backside dielectric layer 150 may include a high-k dielectric material such as HfO₂, ZrO₂, HfAlOₓ, HfSiOₓ, Al₂O₃, Si₃N₄, AlN, BeO, SiC, diamond, the like, or combinations thereof. In some embodiments, a dielectric constant (k value) of the backside dielectric layer 150 is greater than a dielectric constant (k value) of silicon oxide, which is about 3.9. In some embodiments, the dielectric constant (k value) of the backside dielectric layer 150 is in a range from about 5 to about 10. In some embodiments, a dielectric constant (k value) of the backside dielectric layer 150 may be greater than a dielectric constant (k value) of the IMD layer FD and/or a dielectric constant (k value) of the ILD layer 120D. The backside dielectric layer 150 can be an amorphous dielectric layer, a polycrystal dielectric layer, a crystalline dielectric layer, or a combination thereof.

Materials of the high-k backside dielectric layer 150 may be chosen to have a good thermal conductivity (κₜₕ value). In some embodiments, a thermal conductivity (κₜₕ value) of the backside dielectric layer 150 is greater than a thermal conductivity (κₜₕ value) of silicon oxide (e.g., about 1.4 W/mK). For example, the high-k backside dielectric layer 150 may include AlN, BeO, SiC, diamond, the like, or the combination thereof. In some embodiments, the thermal conductivity (κₜₕ value) of the backside dielectric layer 150 is in a range from about 50 W/mK to about 1200 W/mK. In some embodiments, a thermal conductivity (κₜₕ value) of the backside dielectric layer 150 may be greater than a thermal conductivity (κₜₕ value) of the IMD layer FD and/or a thermal conductivity (κₜₕ value) of the ILD layer 120D. In the context, the thermal conductivity (κₜₕ value) is, how easily heat passes across a material. The thermal conductivity (κₜₕ value) is a fundamental property, independent of the quantity of material. It can represents the steady-state heat flow through a unit area of a material resulting from a temperature gradient perpendicular to that unit area. The thermal conductivity (κₜₕ value) can be expressed in W/mK.

In some other embodiments, the high-k backside dielectric layer 150 may be chosen without considering a thermal conductivity (κₜₕ value). For example, the high-k backside dielectric layer 150 may include Al₂O₃, Si₃N₄, the like, or the combination thereof. In such embodiments, a thermal conductivity (κₜₕ value) of the backside dielectric layer 150 may be in a range from about 1 W/mK to about 50 W/mK. In some embodiments, a thermal conductivity (κₜₕ value) of the backside dielectric layer 150 may be equal to or less than a thermal conductivity (κₜₕ value) of the IMD layer FD and/or a thermal conductivity (κₜₕ value) of the ILD layer 120D.

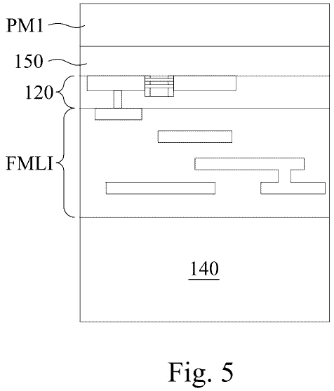

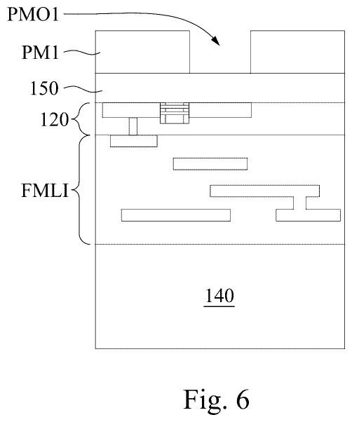

Reference is made to FIGS. 5 and 6. A lithography process (e.g., photolithography or e-beam lithography) is performed to form a resist layer PM1 having openings PMO1 over the backside dielectric layer 150. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The openings PMO1 may be vertically aligned with the backside of the source/drain regions SD of the device DE.

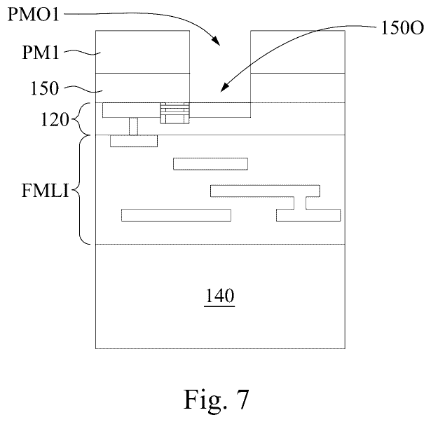

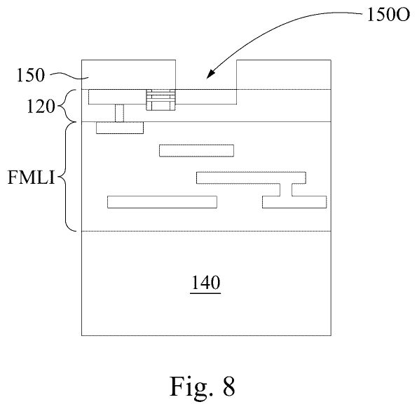

Reference is made to FIG. 7. The backside dielectric layer 150 is etched using the resist layer PM1 as an etch mask, resulting in openings 150O in the backside dielectric layer 150. The etching process may include a dry etch (e.g., reactive ion etching), a wet etch, or the combination thereof. The openings 150O may expose backsides of the source/drain regions SD. After the etching process, the resist layer PM1 is removed from the backside dielectric layer 150 by suitable ashing and/or stripping process, and the resulted structure is shown in FIG. 8.

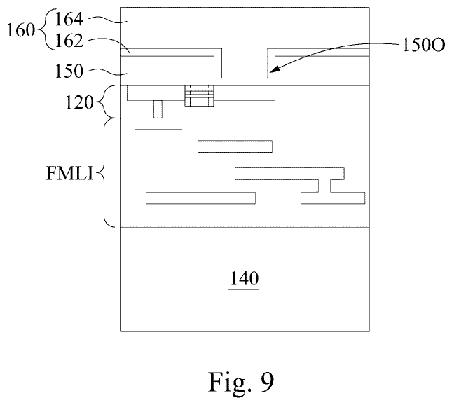

Reference is made to FIG. 9. A metal material 164 is deposited over the backside dielectric layer 150 and into the openings 150O. In some embodiments, the metal material 164 may include Al, W, Ru, Co, Cu, Ti, TiN, Ta, TaN, Mo, Ni, combinations thereof, or the like. The metal materials are deposited to fill the openings 150O by using suitable deposition techniques (e.g., CVD, PVD, ALD, sputter, plating, the like or combinations thereof). In some embodiments, prior to depositing the metal material 164, one or more metal barrier/adhesion layers 162 may be conformally deposited over the backside dielectric layer 150 into the openings 150O. The one or more metal barrier/adhesion layers 162 may comprise titanium, titanium nitride, tantalum, tantalum nitride, or the like, and may be formed using PVD, sputter, plating, ALD, or the like. The one or more metal barrier/adhesion layers 162 can protect the backside dielectric layer 150 from metal diffusion (e.g., copper diffusion) and metallic poisoning.

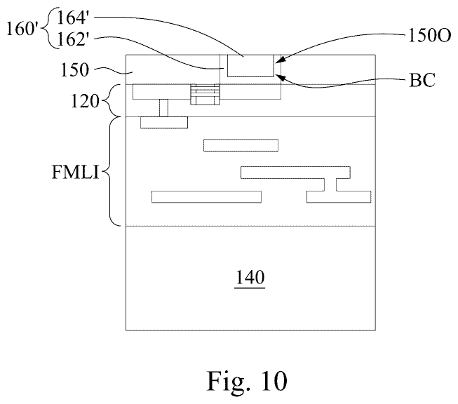

Reference is made to FIG. 10. A planarization process (e.g., a CMP process, or a grinding process) can be performed to remove excess metal materials outside the openings 150O, while leaving metal materials in the openings 150O to serve as a backside contact BC. For example, a first portion of the metal barrier/adhesion layers 162 and a first portion of the metal material 164 (referring to FIG. 9) outside the openings 150O are removed, and a second portion of the metal barrier/adhesion layers 162 and a second portion of the metal material 164 (referring to FIG. 9) in the openings 150O remains. The remaining second portion of the metal barrier/adhesion layers 162 and the remaining second portion of the metal material 164 (referring to FIG. 9) can be referred to as the metal barrier/adhesion layers 162′ and the metal material 164′, which form the backside contact BC. In some embodiments, the shape of the backside contact BC may include circular, rectangular, ellipse, diamond, or the like when viewed from top.

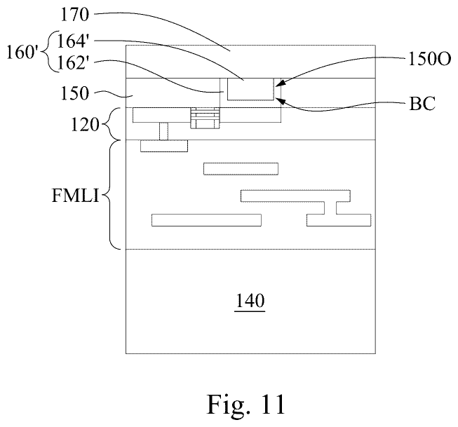

Reference is made to FIG. 11. A backside dielectric layer 170 is deposited over the backside dielectric layer 150 and the backside contact BC, for example, by ALD, CVD, PVD, the like, or the combination thereof. The backside dielectric layer 170 may include a high-k dielectric material such as HfO₂, ZrO₂, HfAlOₓ, HfSiOₓ, Al₂O₃, Si₃N₄, AlN, BeO, SiC, diamond, the like, or combinations thereof. In some embodiments, a dielectric constant (k value) of the backside dielectric layer 170 is greater than a dielectric constant (k value) of silicon oxide, which is about 3.9. In some embodiments, the dielectric constant (k value) of the backside dielectric layer 150 is in a range from about 5 to about 100. In some embodiments, a dielectric constant (k value) of the backside dielectric layer 170 may be greater than a dielectric constant (k value) of the IMD layer FD and/or a dielectric constant (k value) of the ILD layer 120D. The backside dielectric layer 170 can be an amorphous dielectric layer, a polycrystal dielectric layer, a crystalline dielectric layer, or a combination thereof.

Materials of the high-k backside dielectric layer 170 may be chosen to have a good thermal conductivity (κₜₕ value). In some embodiments, a thermal conductivity (κₜₕ value) of the backside dielectric layer 170 is greater than a thermal conductivity (κₜₕ value) of silicon oxide (e.g., about 1.4 W/mK). For example, the high-k backside dielectric layer 170 may include AlN, BeO, SiC, diamond, the like, or the combination thereof. In some embodiments, the thermal conductivity (κₜₕ value) of the backside dielectric layer 170 is in a range from about 100 W/mK to about 3000 W/mK. In some embodiments, a thermal conductivity (κₜₕ value) of the backside dielectric layer 170 may be greater than a thermal conductivity (κₜₕ value) of the IMD layer FD and/or a thermal conductivity (κₜₕ value) of the ILD layer 120D.

In some other embodiments, the high-k backside dielectric layer 170 may be chosen without considering a thermal conductivity (κₜₕ value). For example, the high-k backside dielectric layer 170 may include Al₂O₃, Si₃N₄, the like, or the combination thereof. In such embodiments, a thermal conductivity (κₜₕ value) of the backside dielectric layer 170 may be less than a thermal conductivity (κₜₕ value) of silicon oxide. In such embodiments, a thermal conductivity (κₜₕ value) of the backside dielectric layer 170 may be equal to or less than a thermal conductivity (κₜₕ value) of the IMD layer FD and/or a thermal conductivity (κₜₕ value) of the ILD layer 120D.

In some embodiments, the backside dielectric layer 170 may have a same material as that of the backside dielectric layer 150, and thus having the same dielectric constant (k value) and thermal conductivity (κₜₕ value). In some alternative embodiments, the backside dielectric layer 170 may have a material different from that of the backside dielectric layer 150, and thus having a different dielectric constant (k value) and a different thermal conductivity (κₜₕ value) from that of the backside dielectric layer 150.

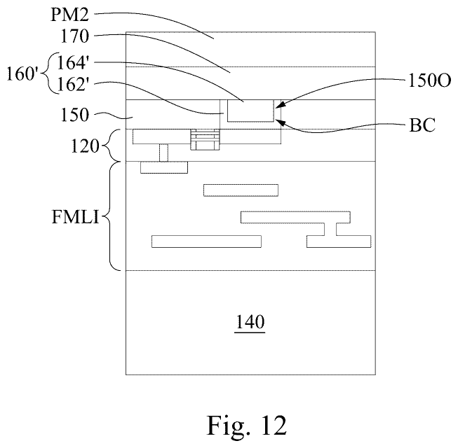

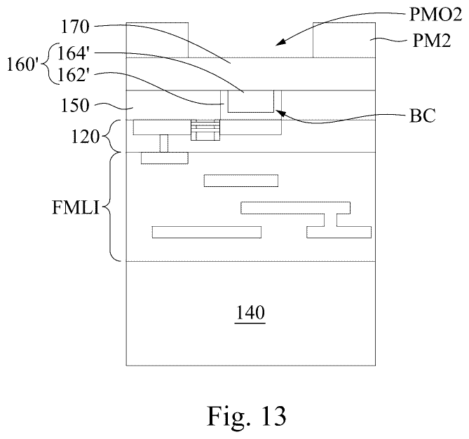

Reference is made to FIGS. 12 and 13. A lithography process (e.g., photolithography or e-beam lithography) is performed to form a resist layer PM2 having openings PMO2 over the backside dielectric layer 170. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The openings PMO2 may be vertically aligned with the backside contact BC and the backside of the source/drain regions SD of the device DE.

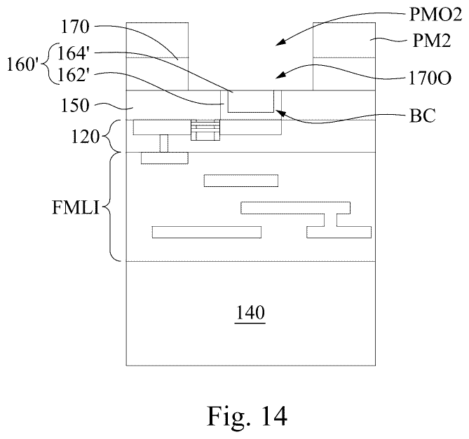

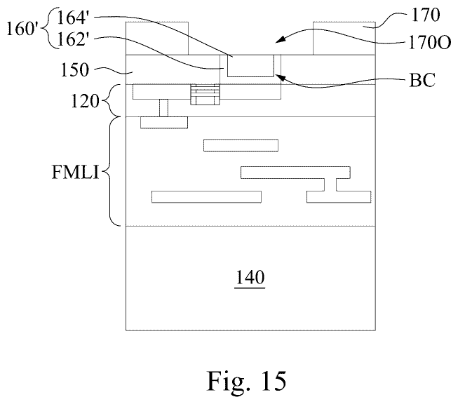

Reference is made to FIG. 14. The backside dielectric layer 170 is etched using the resist layer PM2 as an etch mask, resulting in openings 170O in the backside dielectric layer 170. The etching process may include a dry etch (e.g., reactive ion etching), a wet etch, or the combination thereof. The openings 170O may expose backsides of the backside contact BC. After the etching process, the resist layer PM2 is removed from the backside dielectric layer 170 by suitable ashing and/or stripping process, and the resulted structure is shown in FIG. 15.

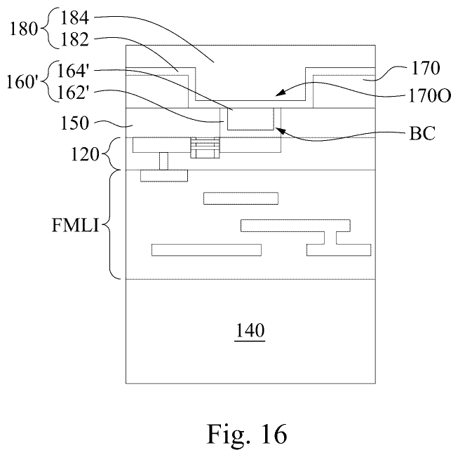

Reference is made to FIG. 16. A metal material 184 is deposited over the backside dielectric layer 170 and into the openings 170O. In some embodiments, the metal material 184 may include Al, W, Ru, Co, Cu, Ti, TiN, Ta, TaN, Mo, Ni, combinations thereof, or the like. The metal materials are deposited to fill the openings 170O by using suitable deposition techniques (e.g., CVD, PVD, ALD, sputter, plating, the like or combinations thereof). In some embodiments, prior to depositing the metal material 184, one or more metal barrier/adhesion layers 182 may be conformally deposited over the backside dielectric layer 170 into the openings 170O. The one or more metal barrier/adhesion layers 182 may comprise titanium, titanium nitride, tantalum, tantalum nitride, or the like, and may be formed using PVD, sputter, plating, ALD, or the like. The one or more metal barrier/adhesion layers 182 can protect the backside dielectric layer 170 from metal diffusion (e.g., copper diffusion) and metallic poisoning.

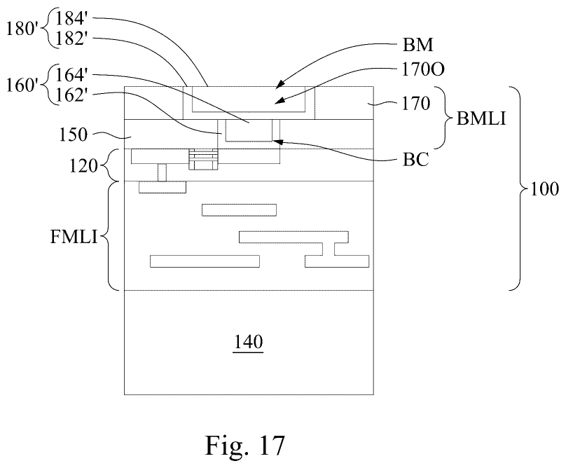

Reference is made to FIG. 17. A planarization process (e.g., a CMP process, or a grinding process) can be performed to remove excess metal materials outside the openings 170O, while leaving metal materials in the openings 170O to serve as a backside metal line BM. For example, a first portion of the metal barrier/adhesion layers 182 and a first portion of the metal material 184 (referring to FIG. 16) outside the openings 170O are removed, and a second portion of the metal barrier/adhesion layers 182 and a second portion of the metal material 184 (referring to FIG. 16) in the openings 170O remains. The remaining second portion of the metal barrier/adhesion layers 182 and the remaining second portion of the metal material 184 (referring to FIG. 16) can be referred to as the metal barrier/adhesion layers 182′ and the metal material 184′, which form the backside metal line BM. In some embodiments, the shape of the backside metal lines BM may include circular, rectangular, ellipse, diamond, or the like when viewed from top. FIGS. 4-17 illustrates formation of a backside metallization layer as a backside MLI structure BMLI. In some embodiments, by repeating the step shown in FIGS. 4-17, plural backside metallization layers are formed and stacked over each other, and the backside MLI structure BMLI may include plural metallization layers.

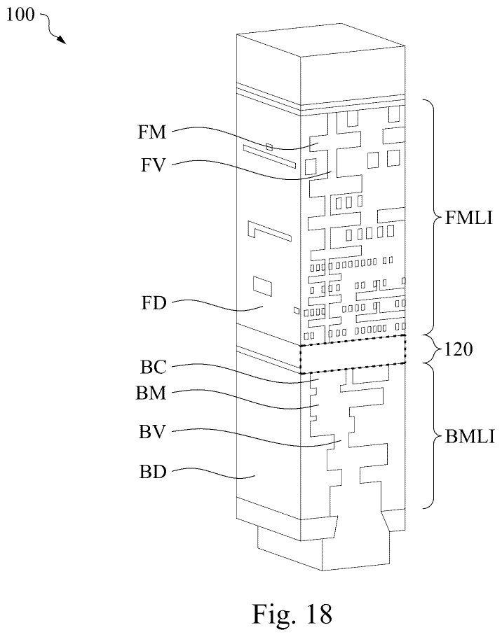

FIG. 18 is a schematic view of an integrated circuit structure 100 according to some embodiments of the present disclosure. The integrated circuit structure 100 includes the device layer 120, the front-side MLI structure FMLI, and the backside MLI structure BMLI. As illustrated above, the front-side MLI structure FMLI is formed over a frontside of the device layer 120, and the backside MLI structure BMLI is formed over a backside of the device layer 120. The backside MLI structure BMLI may include one or more backside metallization layers. The number of backside metallization layers may vary according to design specifications of the integrated circuit structure. The backside metallization layers each comprise one or more backside inter-metal dielectric (IMD) layers BD, one or more horizontal interconnects respectively extending horizontally in the IMD layers (e.g., backside metal lines BM), and one or more vertical interconnects respectively extending vertically in the IMD layers (e.g., backside metal via BV or the backside metal contact BC). The backside metal via BV connects the lower ones of the backside metal lines BM to the upper ones of the backside metal lines BM. In some embodiments, the bottommost metallization layers (e.g., the backside metal contact BC) is in contact with the source/drain region SD to make power electrical connection from the backside metal lines BM to the source/drain region SD. In the context, the backside dielectric layers 150 and 170 can be referred to as the backside IMD layers BD. In some embodiments, a height of the backside metal lines BM is greater than a height of the frontside metal lines FM, and therefore a height of the backside IMD layers BD may be greater than a height of the frontside IMD layers FD.

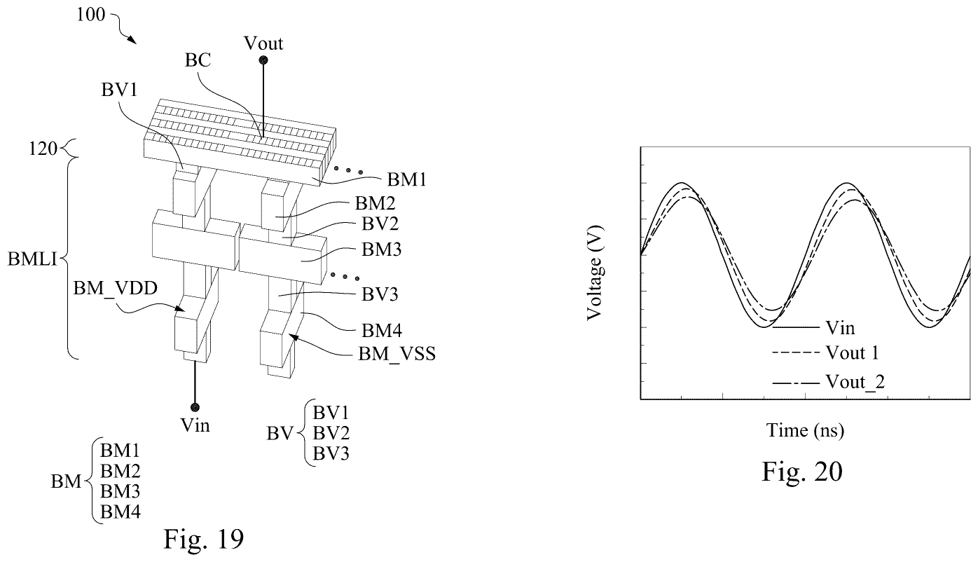

FIG. 19 illustrates a backside MLI structure BMLI according to some embodiments of the present disclosure. The backside MLI structure BMLI may include four metallization layers. The first metallization layer includes backside metal lines BM1 and backside metal contacts BC. The second metallization layer includes backside metal lines BM2 and backside metal vias BV1. The third metallization layer includes backside metal lines BM3 and backside metal vias BV2. The fourth metallization layer includes backside metal lines BM4 and backside metal vias BV3. A first one of the backside metal lines (e.g., a first one of the backside metal lines BM4) can be connected with a high power node, thereby serving as a high power rail BM_VDD. A second one of the backside metal lines (e.g., a second one of the backside metal lines BM4) can be connected with a low power node, thereby serving as a low power rail BM VSS.

FIG. 20 is a diagram illustrating voltage versus time of the integrated circuit structure according to some embodiments of the present disclosure. For example, for the integrated circuit structure including the backside MLI structure BMLI in FIG. 19, a node Vin is connected with the high power rail BM_VDD, while a node Vout is measured. In FIG. 20, the condition “Vin” indicates an input voltage (e.g., sine wave) at the node Vin. The condition “Vout_1” indicate an output voltage at the node Vout for an integrated circuit structure including a low-k backside dielectric layer in the backside MLI structure BMLI. The low-k backside dielectric layer may include silicon oxide. The condition “Vout_2” indicate an output voltage at the node Vout for an integrated circuit structure including a high-k backside dielectric layer in the backside MLI structure BMLI. In some embodiments, the high-k backside dielectric layer may be chosen to have a good thermal conductivity (κₜₕ value), such as AlN, BeO, SiC, diamond, etc. In some embodiments, the high-k backside dielectric layer may be chosen without considering a thermal conductivity (κₜₕ value), such as Al₂O₃, Si₃N₄, etc. FIG. 20 shows that the condition “Vout_2” shows a smaller amplitude than that of the condition “Vout_2”. It can be concluded that the high k dielectric can reduce ground-rail voltage bouncing noise.

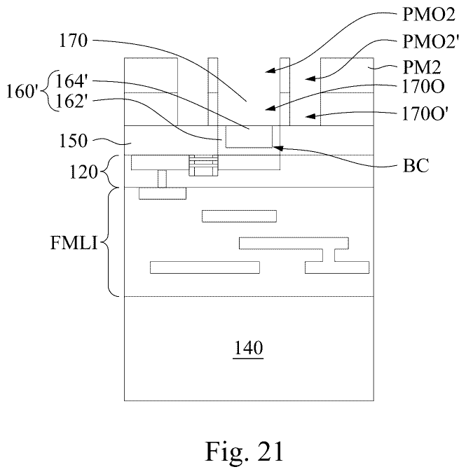

FIGS. 21-23 illustrate a method for fabricating an integrated circuit structure at various intermediate stages of manufacture according to some embodiments of the present disclosure. Details of the present embodiments are similar to those illustrated in the embodiments of FIGS. 1-17, except that backside dummy metals DM are formed in the backside dielectric layer 170 and adjacent to the backside metal line BM.

Reference is made to FIG. 21. A lithography process (e.g., photolithography or e-beam lithography) is performed to form a resist layer PM2 having openings PMO2 and PMO2′ over the backside dielectric layer 170. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The openings PMO2 may be vertically aligned with the backside contact BC and the backside of the source/drain regions SD of the device DE. The openings PMO2′ may be adjacent to the openings PMO2. The openings PMO2′ may be vertically misaligned with the backside contact BC.

After the formation of the resist layer PM2, the backside dielectric layer 170 is etched using the resist layer PM2 as an etch mask, resulting in openings 170O and 170O′ in the backside dielectric layer 170. The openings 170O may expose backsides of the backside contact BC. The openings 170O′ may expose the backside dielectric layer 150 and does not expose any functional features. After the etching process, the resist layer PM2 is can be removed from the backside dielectric layer 170 by suitable ashing and/or stripping process.

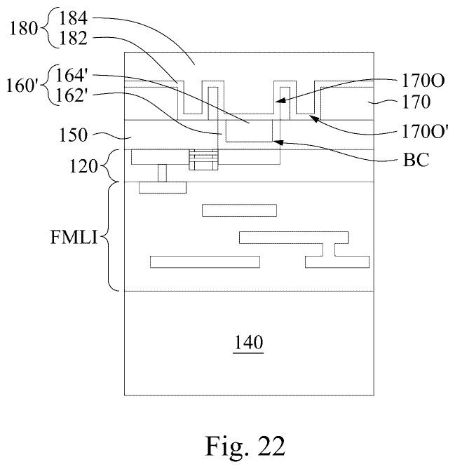

Reference is made to FIG. 22. A metal material 184 is deposited over the backside dielectric layer 170 and into the openings 170O and 170O′. In some embodiments, prior to depositing the metal material 184, one or more metal barrier/adhesion layers 182 may be conformally deposited over the backside dielectric layer 170 into the openings 170O and 170O′. The one or more metal barrier/adhesion layers 182 can protect the backside dielectric layer 170 from metal diffusion (e.g., copper diffusion) and metallic poisoning.

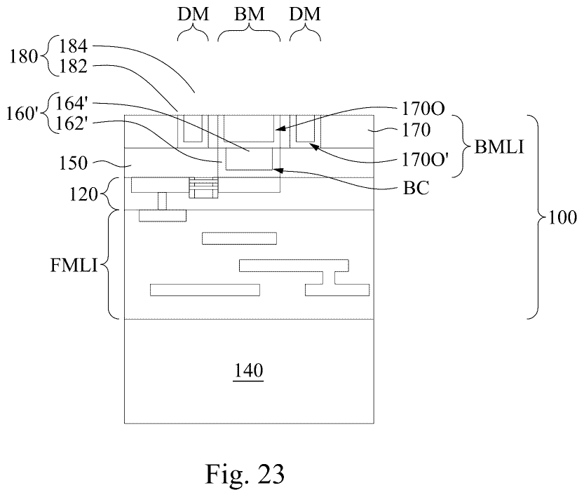

Reference is made to FIG. 23. A planarization process (e.g., a CMP process, or a grinding process) can be performed to remove excess metal materials outside the openings 170O and 170O′, while leaving metal materials in the openings 170O and 170O′. For example, a first portion of the metal barrier/adhesion layers 182 and a first portion of the metal material 184 (referring to FIG. 16) outside the openings 170O and 170O′ are removed, and a second portion of the metal barrier/adhesion layers 182 and a second portion of the metal material 184 (referring to FIG. 16) in the openings 170O and 170O′ remains. The remaining second portion of the metal barrier/adhesion layers 182 and the remaining second portion of the metal material 184 (referring to FIG. 16) can be referred to as the metal barrier/adhesion layers 182′ and the metal material 184′. The metal barrier/adhesion layers 182′ and the metal material 184′ in the openings 170O can form the backside metal line BM. The metal barrier/adhesion layers 182′ and the metal material 184′ in the openings 170O can form the backside dummy metal DM adjacent to the backside metal line BM. The backside dielectric layer 170 can space the backside metal line BM apart from the backside dummy metal DM. By the configuration of the backside metal line BM, the backside dielectric layer 170, and the backside dummy metal DM, a vertical metal-insulator-metal (MIM) structure is formed, thereby increasing parasitic capacitance. Other details of the present embodiments are similar to those illustrated in the embodiments of FIGS. 1-17, and therefore not repeated herein.

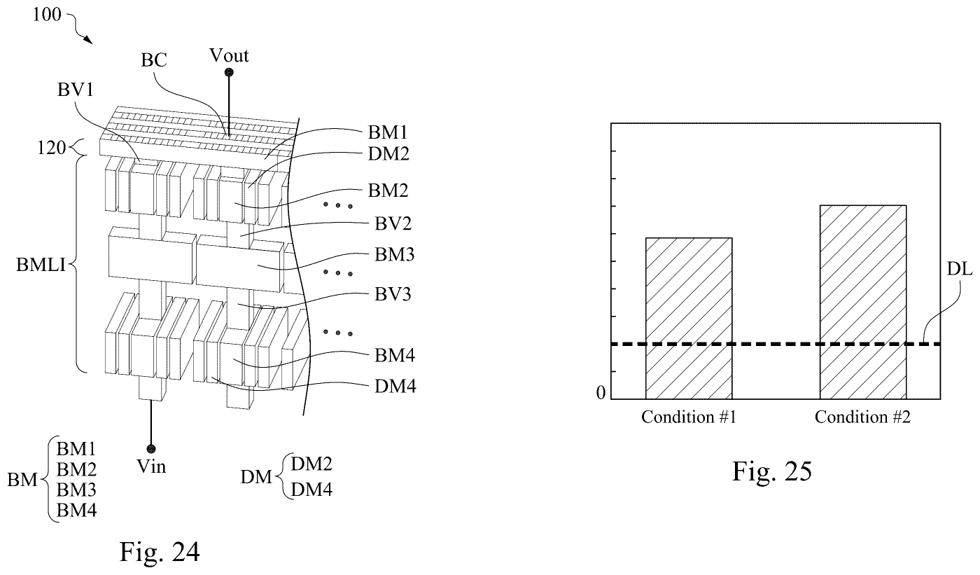

FIG. 24 illustrates a backside MLI structure BMLI according to some embodiments of the present disclosure. The backside MLI structure BMLI may include four metallization layers. The first metallization layer includes backside metal lines BM1 and backside metal contacts BC. The second metallization layer includes backside metal lines BM2, backside dummy metals DM2, and backside metal vias BV1. The third metallization layer includes backside metal lines BM3, and backside metal vias BV2. The fourth metallization layer includes backside metal lines BM4, backside dummy metals DM4, and backside metal vias BV3. By the configuration of the backside dummy metal DM2 and DM4, vertical MIM structures are formed, thereby increasing parasitic capacitance.

FIG. 25 is a diagram illustrating noise reduction of integrated circuit structures with backside high-k dielectrics according to some embodiments of the present disclosure. The noise reduction can be calculated as a result of division, by dividing a difference between a maximum value of an input voltage at the node Vin (referring to FIGS. 19 and 24) and a maximum value of an output voltage at the node Vout (referring to FIGS. 19 and 24) by an amplitude of the input voltage at the node Vin (referring to FIGS. 19 and 24). The condition #1 indicates a noise reduction for an integrated circuit structure including high-k backside dielectric layers but without MIM structures, as the integrated circuit structure shown in FIG. 19. The condition #2 indicates a noise reduction for an integrated circuit structure including high-k backside dielectric layers and with MIM structures in the backside MLI structure BMLI, as shown in FIG. 24. The dashed line DL indicates a noise reduction for an integrated circuit structure including low-k backside dielectric layers, without MIM structures and high-k backside dielectric layers. In FIG. 25, compared to the integrated circuit structure using low-k backside dielectric layers (e.g., the condition indicated by the dashed line DL), the integrated circuit structure including high-k backside dielectric layers have a greater noise reduction (e.g., Condition #1 and Condition #2), for example, by about 2 to about 4 times than the noise reduction for the integrated circuit structure using low-k backside dielectric layers (e.g., the condition indicated by the dashed line DL). Furthermore, compared to the integrated circuit structure without the MIM structures (e.g., Condition #1), the integrated circuit structure with MIM structures have a greater noise reduction (e.g., Condition #2). It can be inferred that the vertical MIM structure can increase parasitic capacitance.

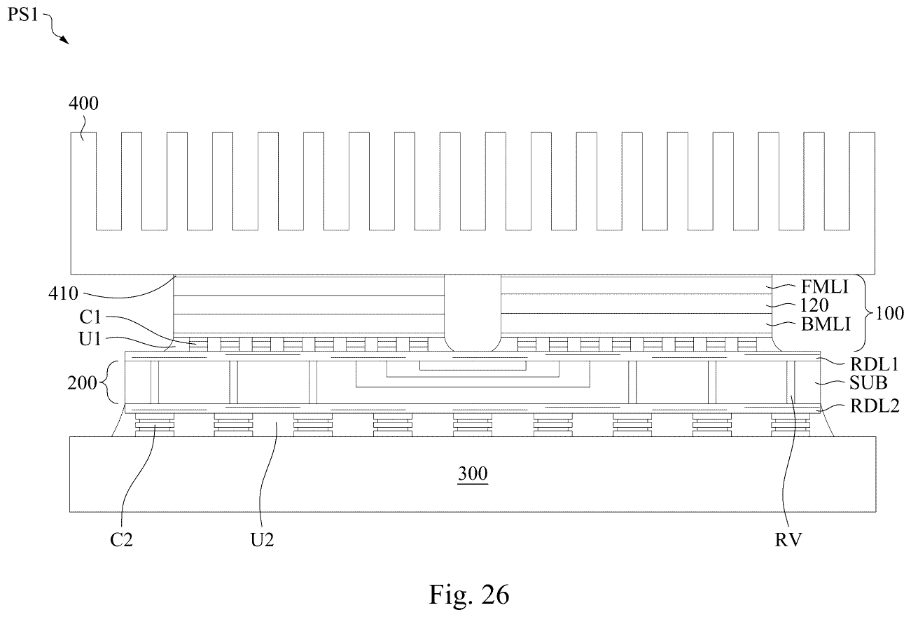

FIG. 26 is a cross-section view of a package structure PS1 according to some embodiments of the present disclosure. The package structure PS1 includes integrated circuit structures 100, an interposer structure 200, a package substrate 300, and a heat dissipation structure 400. In the present embodiments, the integrated circuit structures 100 are semiconductor dies obtained by a singulation process performed after the formation of the backside MLI structure BMLI (referring to FIGS. 17 and 23). Each of the semiconductor dies (e.g., the integrated circuit structure 100) may include the frontside MLI structure FMLI, the device layer 120, and the backside MLI structure BMLI using high-k backside dielectric layers. The interposer structure 200 may include a core layer SUB, plural through vias RV formed in the core layer SUB, and redistribution structures RDL1 and RDL2 on opposite sides of the silicon substrate SUB. In some embodiments, the core layer SUB is a substrate such as a bulk semiconductor substrate (e.g., silicon substrate), silicon on insulator (SOI) substrate or a multi-layered semiconductor material substrate. The redistribution layer RDL1 may include one or more dielectric layers and one or more conductive layers sandwiched between the dielectric layers and electrically and physically connected to connectors C1. The redistribution layer RDL2 may include one or more dielectric layers and one or more conductive layers sandwiched between the dielectric layers and electrically and physically connected to connectors C2.

The integrated circuit structure 100 is bonded with the redistribution structure RDL1 of the interposer structure 200 by the connectors C1. The package substrate 300 is bonded with the redistribution structure RDL2 of the interposer structure 200 by the connectors C2. In some embodiments, the package substrate 300 is a printed circuit board, including metallization layers and vias are embedded in the package substrate 300 and together provide routing function for the package substrate 300. The high-k backside dielectric layers of the backside MLI structure BMLI may have a high thermal conductivity (κₜₕ value), which can reduce the thermal resistance to reduce the junction temperature. In some embodiments of the present disclosure, the backside MLI structure BMLI using high-k backside dielectric layers is placed near the interposer structure 200 for receiving electrical power from the package substrate 300 with good thermal dissipation ability.

In some embodiments, the heat dissipation structure 400 is a heat sink comprising a base and plural fin structures supported by a base. The heat dissipation structure 400 is attached to the integrated circuit structure 100 by a thermal interface material 410. In some embodiments, the thermal interface material 410 may be a polymer having a good thermal conductivity (Tk). In some embodiments, the thermal interface material 410 may include a polymer with thermal conductive fillers. Applicable thermal conductive filler materials may include aluminum oxide, boron nitride, aluminum nitride, aluminum, copper, silver, indium, a combination thereof, or the like. In other embodiments, the thermal interface material 410 may comprise other materials such as a metallic-based or solder-based material comprising silver, indium paste, or the like.

Underfill U1 may be formed to cover the electrical connectors C1, and to fill up the spaces in between the semiconductor dies (e.g., the integrated circuit structure 100) and the interposer structure 200. Underfill U2 may be formed to cover the electrical connectors C2, and to fill up the spaces in between the interposer structure 200 and the package substrate 300.

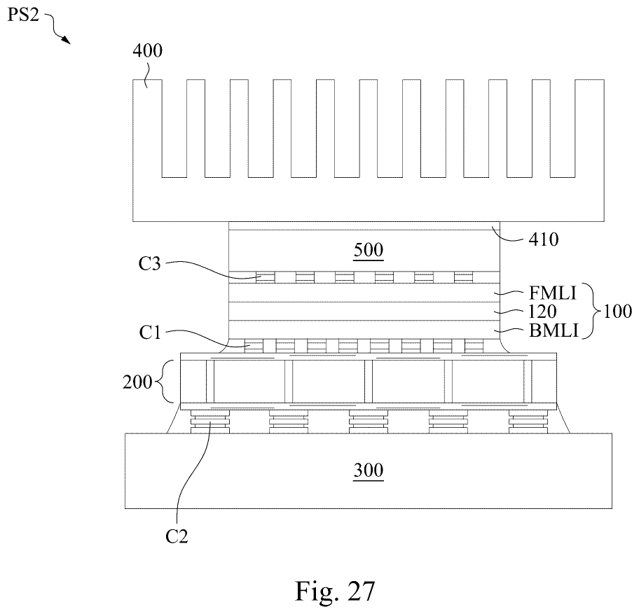

FIG. 27 is a cross-section view of a package structure PS2 according to some embodiments of the present disclosure. Details of the present embodiments are similar to those illustrated in FIG. 26, except that the package structure PS2 further include another integrated circuit structure (or another semiconductor die) 500 stacked over the integrated circuit structure 100. As aforementioned, the integrated circuit structure 100 is a semiconductor die obtained by a singulation process performed after the formation of the backside MLI structure BMLI (referring to FIGS. 17 and 23). The semiconductor die (e.g., the integrated circuit structure 100) may include the frontside MLI structure FMLI, the device layer 120, and the backside MLI structure BMLI using high-k backside dielectric layers. The integrated circuit structure 500 is bonded with the integrated circuit structure 100 by the connectors C3. And, the heat dissipation structure 400 is attached to the integrated circuit structure 500 by a thermal interface material 410. Other details of the present embodiments are similar to those illustrated in FIG. 26, and therefore not repeated herein.

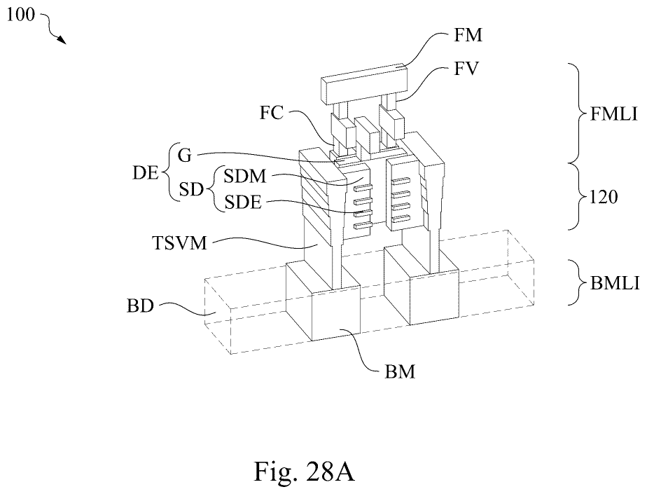

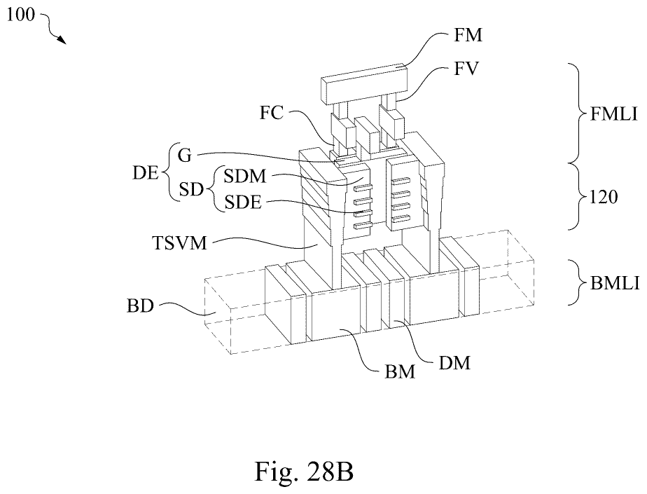

FIG. 28A is a schematic view of an integrated circuit structure according to some embodiments of the present disclosure. Details of the present embodiments are similar to those illustrated above with respect to FIG. 17, except that the source/drain regions SD are electrically connected to the backside metal lines BM by through-silicon vias TSVM. The through-silicon vias TSVM can be formed in the device layer 120. The through-silicon vias TSV may extend from a bottom of the front-side MLI structure FMLI to the backside metal lines BM. In some embodiments, the through-silicon vias TSV can laterally in contact with the source/drain regions SD, thereby achieving the electrical (power) connections. As aforementioned, the backside metal lines BM are surrounded by the high-k backside IMD layer BD. Other details of the present disclosure are similar to those illustrated above, and therefore not repeated herein. In the context, the source/drain regions SD may include an epitaxial feature SDE and a metal/alloy feature SDM.

FIG. 28B is a schematic view of an integrated circuit structure according to some embodiments of the present disclosure. Details of the present embodiments are similar to those illustrated above with respect to FIG. 28A, except that backside dummy metals DM are used in the present embodiments. As aforementioned, the backside metal lines BM and the backside dummy metals DM are surrounded by the high-k backside IMD layer BD. Other details of the present disclosure are similar to those illustrated above, and therefore not repeated herein.

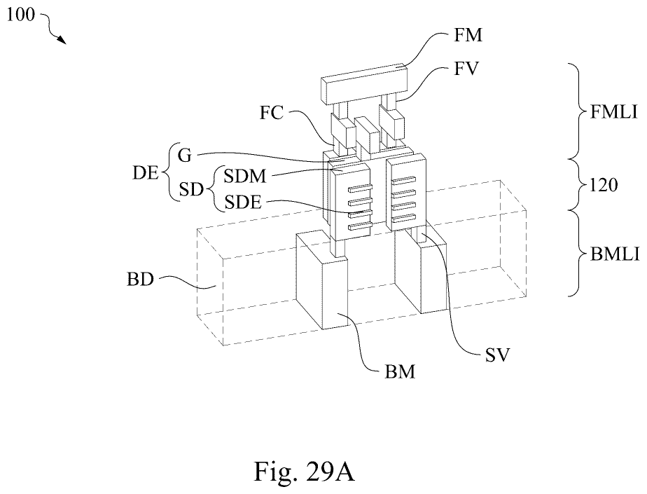

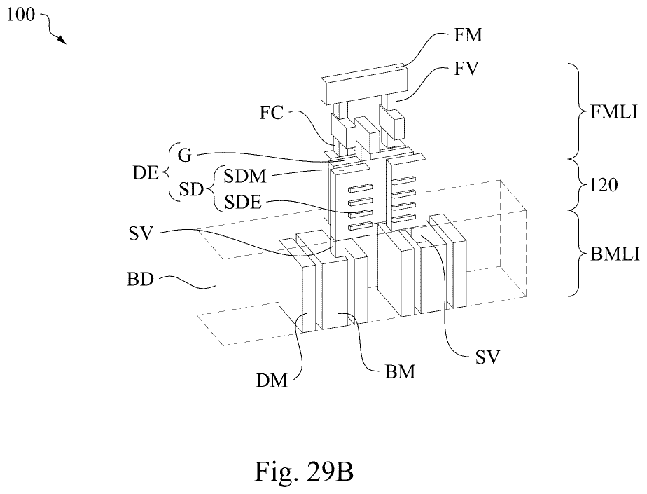

FIG. 29A is a schematic view of an integrated circuit structure according to some embodiments of the present disclosure. Details of the present embodiments are similar to those illustrated above with respect to FIG. 17, except that source/drain regions SD are electrically connected to the backside metal lines BM by self-aligned front-to-back vias SV, which may serve as buried power rails. The self-aligned front-to-back vias SV can be formed in the device layer 120. The self-aligned front-to-back vias SV may be fabricated from the frontside of the substrate in a self-align manner. For example, the conductive materials of the self-aligned front-to-back vias SV is deposited into a deep source/drain opening, and etched back to lower a top surface of the self-aligned front-to-back vias SV, follow by forming source/drain regions SD in the deep source/drain opening and over the self-aligned front-to-back vias SV. As aforementioned, the backside metal lines BM are surrounded by the high-k backside IMD layer BD. Other details of the present disclosure are similar to those illustrated above, and therefore not repeated herein.

FIG. 29B is a schematic view of an integrated circuit structure according to some embodiments of the present disclosure. Details of the present embodiments are similar to those illustrated above with respect to FIG. 29A, except that backside dummy metals DM are used in the present embodiments. As aforementioned, the backside metal lines BM and the backside dummy metals DM are surrounded by the high-k backside IMD layer BD. Other details of the present disclosure are similar to those illustrated above, and therefore not repeated herein.

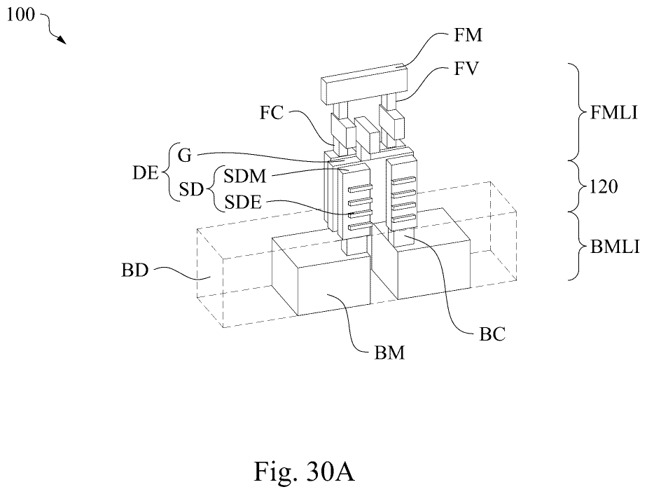

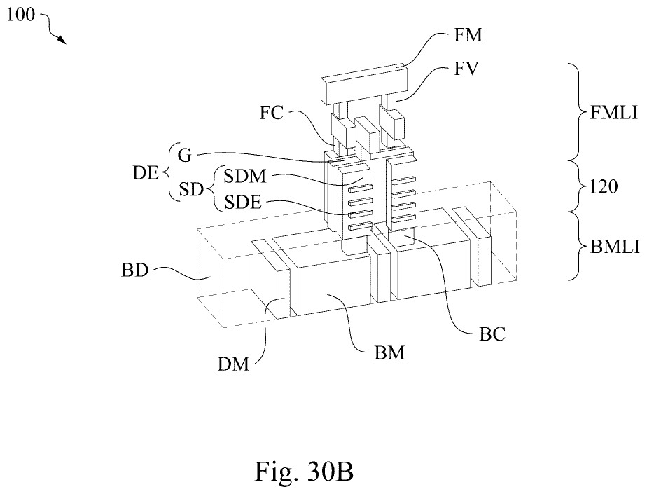

FIG. 30A is a schematic view of an integrated circuit structure according to some embodiments of the present disclosure. Details of the present embodiments are similar to those illustrated above with respect to FIG. 17, except that the backside contact BC connecting the source/drain regions SD to the backside metal lines BM only connects to the bottom of the epitaxial feature SDE of the source/drain regions SD. Stated differently, the backside contact BC is not in contact with the metal/alloy feature SDM of the source/drain regions SD. As aforementioned, the backside metal lines BM are surrounded by the high-k backside IMD layer BD. Other details of the present disclosure are similar to those illustrated above, and therefore not repeated herein.

FIG. 30B is a schematic view of an integrated circuit structure according to some embodiments of the present disclosure. Details of the present embodiments are similar to those illustrated above with respect to FIG. 30A, except that backside dummy metals DM are used in the present embodiments. As aforementioned, the backside metal lines BM and the backside dummy metals DM are surrounded by the high-k backside IMD layer BD. Other details of the present disclosure are similar to those illustrated above, and therefore not repeated herein.

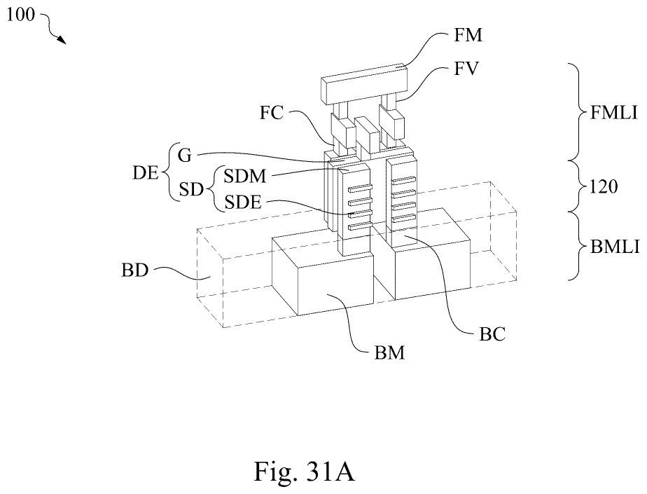

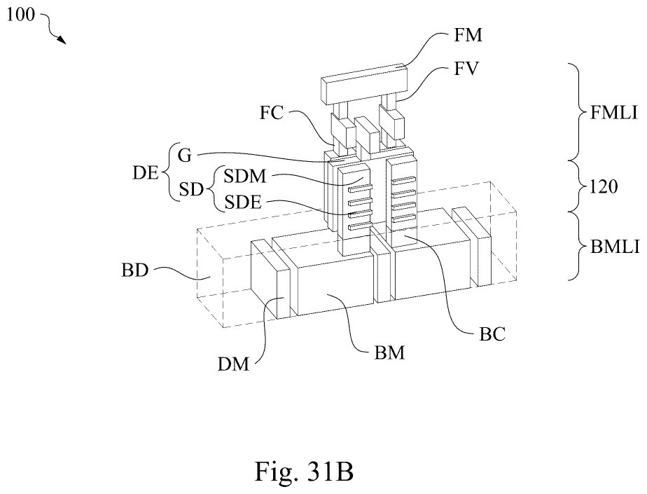

FIG. 31A is a schematic view of an integrated circuit structure according to some embodiments of the present disclosure. Details of the present embodiments are similar to those illustrated above with respect to FIG. 30A, except that the backside contact BC connecting the source/drain regions SD to the backside metal lines BM connects to both the bottom of the epitaxial feature SDE of the source/drain regions SD and the bottom of the metal/alloy feature SDM of the source/drain regions SD. As aforementioned, the backside metal lines BM are surrounded by the high-k backside IMD layer BD. Other details of the present disclosure are similar to those illustrated above, and therefore not repeated herein.

FIG. 31B is a schematic view of an integrated circuit structure according to some embodiments of the present disclosure. Details of the present embodiments are similar to those illustrated above with respect to FIG. 31A, except that backside dummy metals DM are used in the present embodiments. As aforementioned, the backside metal lines BM and the backside dummy metals DM are surrounded by the high-k backside IMD layer BD. Other details of the present disclosure are similar to those illustrated above, and therefore not repeated herein.

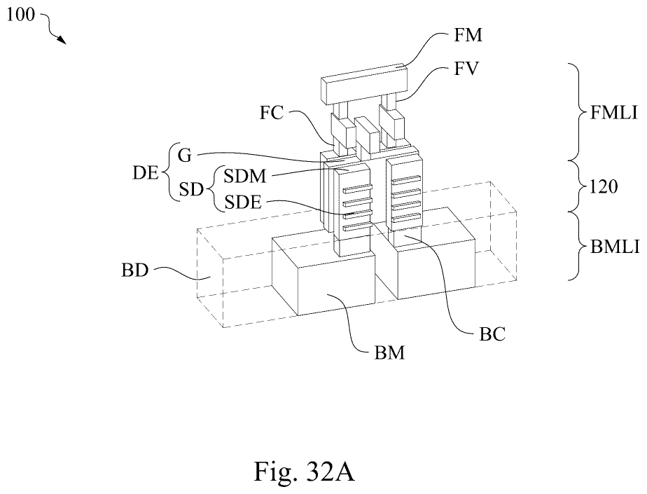

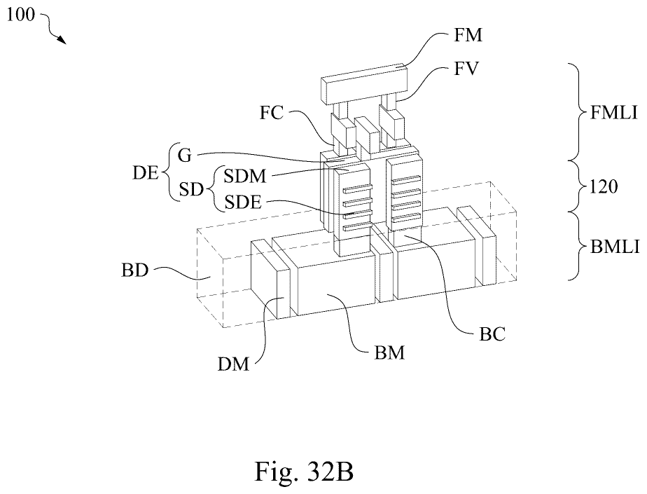

FIG. 32A is a schematic view of an integrated circuit structure according to some embodiments of the present disclosure. Details of the present embodiments are similar to those illustrated above with respect to FIG. 31A, except that a size of the backside contact BC is enlarged by reducing a gate cut and increasing a width of the active region. Other details of the present disclosure are similar to those illustrated above, and therefore not repeated herein.

FIG. 32B is a schematic view of an integrated circuit structure according to some embodiments of the present disclosure. Details of the present embodiments are similar to those illustrated above with respect to FIG. 32A, except that backside dummy metals DM are used in the present embodiments. As aforementioned, the backside metal lines BM and the backside dummy metals DM are surrounded by the high-k backside IMD layer BD. Other details of the present disclosure are similar to those illustrated above, and therefore not repeated herein.

Based on the above discussions, it can be seen that the present disclosure offers advantages to the integrated circuit structure. It is understood, however, that other embodiments may offer additional advantages, and not all advantages are necessarily disclosed herein, and that no particular advantage is required for all embodiments. One advantage is that a backside power delivery structure using an insulator with high dielectric constant to increase the capacitance, thereby enhancing noise reduction, which in turn will stabilize the power lines. Another advantage is that the backside power delivery structure using an insulator with high thermal conductivity to improve the heat dissipation. Still another advantage is that the integrated circuit structure may further include a vertical MIM structure to increase parasitic capacitance, thereby enhancing noise reduction.

According to some embodiments of the present disclosure, a method for fabricating an integrated circuit structure is provided. The method includes forming a semiconductor device over a semiconductor substrate, wherein the semiconductor device comprises a gate structure and first and second source/drain regions respectively on opposite sides of the gate structure; forming a frontside interconnect structure over a frontside of the semiconductor device, wherein the frontside interconnect structure comprise a frontside metal line and a frontside dielectric layer, and the frontside metal line is electrically connected to the first source/drain region of the semiconductor device; depositing a first high-k dielectric layer over a backside of the semiconductor device, wherein a dielectric constant of the first high-k dielectric layer is greater than about 3.9; etching a first opening in the first high-k dielectric layer to expose a backside of the second source/drain region; and forming a first backside metal feature in the first opening in the first high-k dielectric layer.

According to some embodiments of the present disclosure, a method for fabricating an integrated circuit structure is provided. The method includes forming a semiconductor device over a semiconductor substrate, wherein the semiconductor device comprises a gate structure and first and second source/drain regions respectively on opposite sides of the gate structure; forming a frontside interconnect structure over a frontside of the semiconductor device, wherein the frontside interconnect structure comprise a frontside metal line and a frontside dielectric layer, and the frontside metal line is electrically connected to the first source/drain region of the semiconductor device; depositing a first high-k dielectric layer over a backside of the semiconductor device, wherein a thermal conductivity of the first high-k dielectric layer is greater than about 1.4 W/mK; and forming a first backside metal feature in the first high-k dielectric layer.

According to some embodiments of the present disclosure, an integrated circuit structure includes a semiconductor device, a frontside metal line, a frontside dielectric layer, a backside metal line, and a backside dielectric layer. The semiconductor device includes a gate structure and first and second source/drain regions respectively on opposite sides of the gate structure. The frontside metal line is over a frontside of the semiconductor device and electrically connected to the first source/drain region of the semiconductor device. The frontside dielectric layer has a first dielectric constant and surrounds the frontside metal line. The backside metal line is over a backside of the semiconductor device and electrically connected to the second source/drain region of the semiconductor device. The backside dielectric layer has a second dielectric constant and surrounds the backside metal line. The second dielectric constant is greater than the first dielectric constant.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for fabricating an integrated circuit structure, comprising:
forming a semiconductor device over a semiconductor substrate, wherein the semiconductor device comprises a gate structure and first and second source/drain regions respectively on opposite sides of the gate structure;
forming a frontside interconnect structure over a frontside of the semiconductor device, wherein the frontside interconnect structure comprise a frontside metal line and a frontside dielectric layer, and the frontside metal line is electrically connected to the first source/drain region of the semiconductor device;
depositing a first high-k dielectric layer over a backside of the semiconductor device, wherein a dielectric constant of the first high-k dielectric layer is greater than about 3.9;
etching an first opening in the first high-k dielectric layer to expose a backside of the second source/drain region; and
forming a first backside metal feature in the first opening in the first high-k dielectric layer.

2. The method of claim 1, wherein the dielectric constant of the first high-k dielectric layer in a range from about 5 to about 10.

3. The method of claim 1, wherein the dielectric constant of the first high-k dielectric layer is greater than a dielectric constant of the frontside dielectric layer.

4. The method of claim 1, wherein forming the first backside metal feature comprises:
depositing a metal material over the first high-k dielectric layer and into the first opening in the first high-k dielectric layer; and
planarizing the metal material until the first high-k dielectric layer is exposed.

5. The method of claim 4, further comprising:
depositing a metal barrier layer into the first opening in the first high-k dielectric layer prior to depositing the metal material.

6. The method of claim 1, further comprising:
depositing a second high-k dielectric layer over the second high-k dielectric layer, wherein a dielectric constant of the second high-k dielectric layer is greater than about 3.9;
etching a second opening in the second high-k dielectric layer to expose the first backside metal feature; and
forming a second backside metal feature over the first backside metal feature.

7. The method of claim 6, wherein forming the second backside metal feature comprises:
depositing a metal material over the second high-k dielectric layer and into the second opening in the second high-k dielectric layer; and
planarizing the metal material until the second high-k dielectric layer is exposed.

8. The method of claim 6, wherein the first and second high-k dielectric layers comprise different materials.

9. The method of claim 6, wherein the first and second high-k dielectric layers comprise a same material.

10. A method for fabricating an integrated circuit structure, comprising:
forming a semiconductor device over a semiconductor substrate, wherein the semiconductor device comprises a gate structure and first and second source/drain regions respectively on opposite sides of the gate structure;
forming a frontside interconnect structure over a frontside of the semiconductor device, wherein the frontside interconnect structure comprise a frontside metal line and a frontside dielectric layer, and the frontside metal line is electrically connected to the first source/drain region of the semiconductor device;
depositing a first high-k dielectric layer over a backside of the semiconductor device, wherein a thermal conductivity of the first high-k dielectric layer is greater than about 1.4 W/mK; and
forming a first backside metal feature in the first high-k dielectric layer.

11. The method of claim 10, wherein the thermal conductivity of the first high-k dielectric layer is in a range from about 50 W/mK to about 1200 W/mK.

12. The method of claim 10, wherein the thermal conductivity of the first high-k dielectric layer is greater than a thermal conductivity of the frontside dielectric layer.

13. The method of claim 10, further comprising:
depositing a second high-k dielectric layer over the second high-k dielectric layer, wherein a thermal conductivity of the second high-k dielectric layer is greater than about 1.4 W/mK; and
forming a second backside metal feature in the second high-k dielectric layer and over the first backside metal feature.

14. The method of claim 13, wherein the thermal conductivity of the second high-k dielectric layer is greater than a thermal conductivity of the frontside dielectric layer.

15. An integrated circuit structure, comprises:
a semiconductor device comprising a gate structure and first and second source/drain regions respectively on opposite sides of the gate structure;
a frontside metal line over a frontside of the semiconductor device and electrically connected to the first source/drain region of the semiconductor device;
a frontside dielectric layer having a first dielectric constant and surrounding the frontside metal line;
a backside metal line over a backside of the semiconductor device and electrically connected to the second source/drain region of the semiconductor device; and
a backside dielectric layer having a second dielectric constant and surrounding the backside metal line, wherein the second dielectric constant is greater than the first dielectric constant.

16. The integrated circuit structure of claim 15, wherein the second dielectric constant of the backside dielectric layer is greater than about 3.9.

17. The integrated circuit structure of claim 15, wherein a thermal conductivity of the backside dielectric layer is in a range from about 50 W/mK to about 1200 W/mK.

18. The integrated circuit structure of claim 15, wherein a thermal conductivity of the backside dielectric layer is greater than a thermal conductivity of the frontside dielectric layer.

19. The integrated circuit structure of claim 15, wherein the backside dielectric layer and the backside metal line form a backside interconnect structure, the integrated circuit structure further comprising:
an interposer structure bonded with the backside interconnect structure.

20. The integrated circuit structure of claim 15, wherein a height of the backside metal line is greater than a height of the frontside metal line.
